(19) United States
(12) Patent Application Publication
(10) Pub. No.: US 2009/0239178 A1
(43) Pub. Date: Sep. 24, 2009

(54) OPTICAL ATTENUATOR PLATE, EXPOSURE APPARATUS, EXPOSURE METHOD, AND DEVICE MANUFACTURING METHOD

(75) Inventors: Junji Ikeda, Kumagaya-shi (JP); Hideki Komatsuda, Ageo-shi (JP)

Correspondence Address: KLARQUIST SPARKMAN, LLP, 121 SW SALMON STREET, SUITE 1600, PORTLAND, OR, 97204, US

(73) Assignee: Nikon Corporation

(21) Appl. No.: 12/432,589

(22) Filed: Apr. 29, 2009

Related U.S. Application Data
(63) Continuation of application No. PCT/JP2007/071105, filed on Oct. 30, 2007.

(30) Foreign Application Priority Data
Nov. 1, 2006 (JP) 2006-298167

(51) Int. Cl. G03F 7/20; G02B 5/22; G03B 27/42

(52) U.S. Cl. 430/322; 359/888; 355/53

(57) ABSTRACT

There is disclosed an optical attenuator plate and an optical attenuator plate to adjust a quantity of light from a light source, which has a plurality of high-transmittance regions with a relatively high transmittance, and in which shapes of the high-transmittance regions are so defined that an intensity distribution of diverging light or converging light having passed through the optical attenuator plate becomes uniform.

### CROSS-REFERENCE TO RELATED APPLICATIONS

This application is a continuation of, and claims priority to and the benefit of, International Application No. PCT/JP2007/071105 filed on Oct. 30, 2007, which claims priority to and the benefit of Japanese Patent Application No. 2006-298167 filed on Nov. 1, 2006, the entire contents of which are incorporated herein by reference.

### BACKGROUND

1. Field

The present invention relates to an optical attenuator plate (ND) used for adjusting the illuminance on an exposure target surface in exposure apparatus for lithography of semiconductor integrated circuits and the like, an exposure apparatus with the optical attenuator plate, and an exposure method and device manufacturing method using the exposure apparatus. Particularly, the present invention relates to an optical attenuator plate to uniformize an intensity distribution of light having passed therethrough, an exposure apparatus with the optical attenuator plate, and an exposure method and device manufacturing method using the exposure apparatus.

2. Description of the Related Art

U.S. Pat. No. 6,594,334 discloses use of an optical attenuator plate to adjust the illuminance on an exposure target surface, in exposure apparatus for lithography of semiconductor integrated circuits and the like. This optical attenuator plate is arranged so as to adjust the quantity of passing light, in an optical path, for example, upstream of an illumination optical system of the exposure apparatus.

The optical attenuator plate adjusts the illuminance on the exposure target surface by controlling the quantity of light passing through a plurality of openings therein. Light impinging upon the region other than the openings of the optical attenuator plate is absorbed by the optical attenuator plate. The energy of the absorbed light is accumulated as heat in the optical attenuator plate. Therefore, in order to keep the temperature of the optical attenuator plate at a reasonable level, the optical attenuator plate needs to be made thick enough to secure a predetermined thermal capacity.

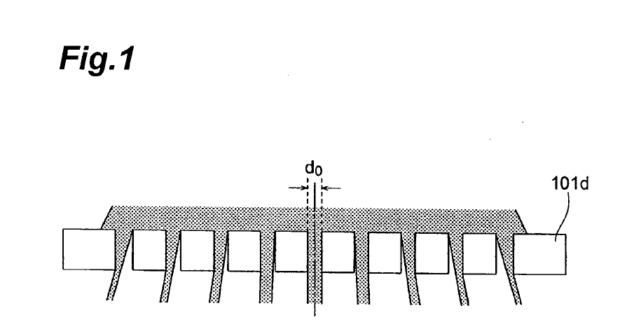

FIG. 1 is a drawing schematically showing a configuration of a conventional optical attenuator plate in a cross section perpendicular to an acceptance surface thereof. In a case where light impinging upon the optical attenuator plate is diverging light, the quantity of light passing through each opening in a peripheral region of the optical attenuator plate is extremely reduced as compared with the quantity of light (shaded regions) passing through an opening at the center of the optical attenuator plate, as shown in FIG. 1. This is because the optical attenuator plate is so thick as to cause vignetting in the openings, for light with large angles to the direction perpendicular to the acceptance surface of the optical attenuator plate. Therefore, the intensity distribution of diverging light having passed through the conventional optical attenuator plate is non-uniform; the intensity of light on the exposure target surface varies depending on locations where the light passes through the optical attenuator plate. In a case where the light impinging upon the optical attenuator plate is converging light, the intensity distribution of converging light having passed through the conventional optical attenuator plate is also non-uniform; the intensity of light on the exposure target surface also varies depending on locations where the light passes through the optical attenuator plate.

There is a demand for an optical attenuator plate capable of uniformizing the intensity distribution of passed light in the case where the light impinging upon the optical attenuator plate is diverging light or converging light.

### SUMMARY

An optical attenuator plate according to the present invention comprises a plurality of high-transmittance regions with a relatively high transmittance. The shapes of the high-transmittance regions are so defined that an intensity distribution of a beam of diverging light or converging light having passed through the optical attenuator plate becomes uniform.

With the optical attenuator plate according to the present invention, the intensity distribution of the beam of diverging light or converging light having passed through the optical attenuator plate becomes uniform. The intensity of the diverging light or converging light beam on an exposure target surface does not vary depending on locations (positions) where the light passes through the optical attenuator plate.

The optical attenuator plate according to the present invention is characterized in that a size of a cross section parallel to an acceptance surface of the optical attenuator plate, of at least one of the plurality of high-transmittance regions, varies along a traveling direction of the light beam.

According to the embodiment of the present invention, the size of the cross section parallel to the acceptance surface of the optical attenuator plate, of at least one of the plurality of high-transmittance regions, varies along the traveling direction of the light beam so that the intensity distribution of the light having passed through the optical attenuator plate becomes uniform. Therefore, the intensity of light on the exposure target surface does not vary depending on locations where the light passes through the optical attenuator plate.

According to an embodiment of the present invention, each opening has a portion of a circular cylinder shape on the center side of the optical attenuator plate; therefore, an opening-opening distance (a value obtained by subtracting a diameter of the openings from a pitch of the openings) on a surface on the non-illuminant side becomes larger than that in a case where the whole opening is of a circular truncated cone shape. Therefore, it becomes easier to manufacture the optical attenuator plate.

The optical attenuator plate according to another embodiment of the present invention is characterized in that, among the plurality of high-transmittance regions, a size of each one in an outside region is larger than a size of each one in an inside region so that the intensity distribution of the light having passed through the optical attenuator plate becomes uniform.

According to the embodiment of the present invention, among the plurality of high-transmittance regions, the size of each one in an outside region is larger than the size of each one in the inside region so that the intensity distribution of the light having passed through the optical attenuator plate becomes uniform. Therefore, the intensity of light on the exposure target surface does not vary depending on locations where the light passes through the optical attenuator plate.

### BRIEF DESCRIPTION OF THE DRAWINGS

A general configuration that implements the various features of the invention will now be described with reference to the drawings. The drawings and the associated descriptions are provided to illustrate embodiments of the invention and not to limit the scope of the invention.

### DESCRIPTION OF THE EMBODIMENTS

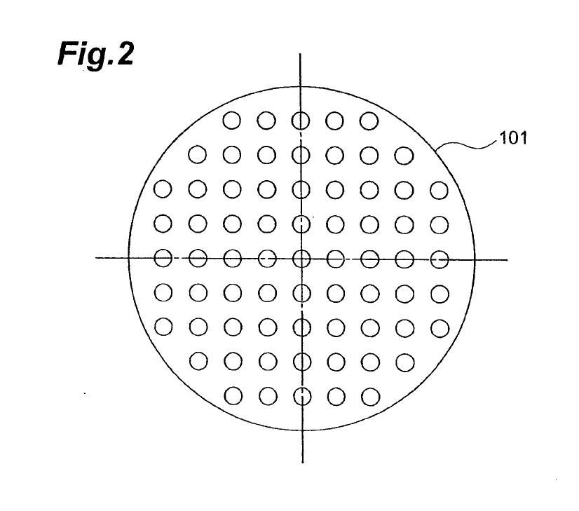

FIG. 2 is a plan view of an optical attenuator plate according to an embodiment of the present invention.

The optical attenuator plate adjusts the quantity of light passing through the optical attenuator plate, in such a manner that the region other than openings absorbs light. The diameter of the openings and the center-center interval of the openings (hereinafter referred to as the pitch) are so defined as to realize the quantity of light to be reduced. The thickness of the optical attenuator plate is defined in consideration of the quantity of light to be absorbed, i.e., the amount of heat. A material of the optical attenuator plate can be a metal with a high melting point and high thermal conductivity. Specifically, in a case where the optical attenuator plate is used in an exposure apparatus for EUV (Extreme Ultraviolet) lithography (hereinafter referred to as an EUV exposure apparatus) using soft X-rays in the wavelength range of approximately 11 to 14 nm, the material of the optical attenuator plate can be molybdenum or tungsten or a compound containing either of the foregoing metals.

The regions corresponding to the openings may be made of a material with a high transmittance such as zirconium, instead of the openings.

By way of example, the size of the optical attenuator plate is as follows.

| | |
|---|---|
| Effective diameter | 80 mm |
| Diameter of openings | 2.3 mm |
| Pitch of openings | 2.6 mm |
| Thickness | 0.3 mm |

It should be noted that the size of the optical attenuator plate is by no means limited to the above size.

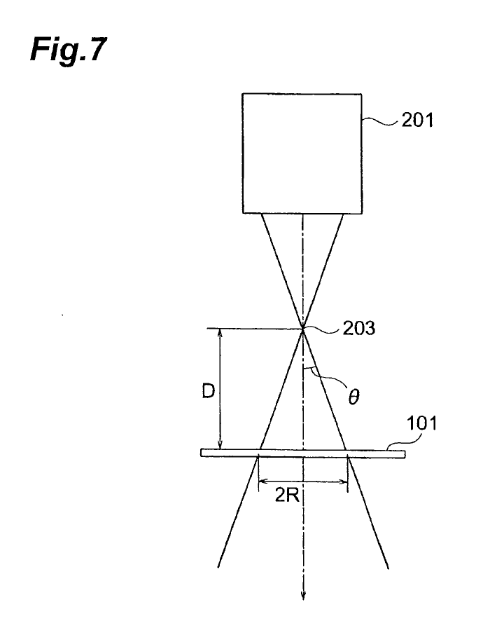

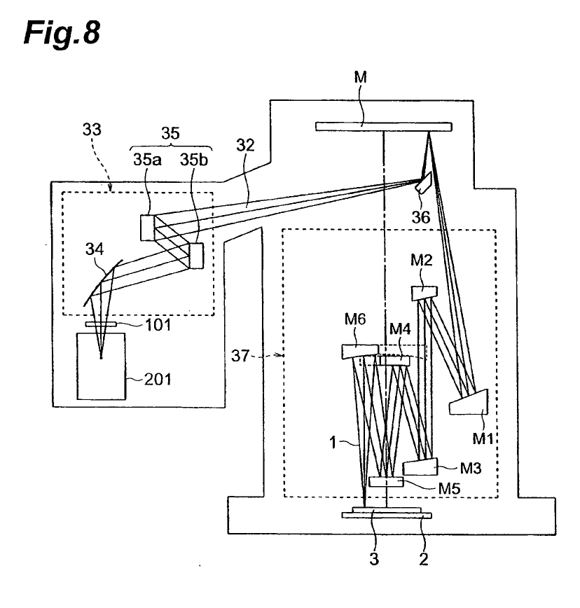

FIG. 7 is a drawing showing a part of an optical system in an exposure apparatus incorporating the optical attenuator plate 101. Light from a light source 201 travels via an intermediate focal point 203 to become diverging light, and the diverging light reaches the optical attenuator plate 101. In FIG. 8, the distance between intermediate focal point 203 and optical attenuator plate 101 is denoted by D, the effective radius of the optical attenuator plate is denoted by R, and the divergence angle from the intermediate focal point 203 is denoted by θ. Light having passed through the optical attenuator plate 101 travels toward an illumination optical system of the exposure apparatus.

Numerical values by way of example only are as follows.

| D | 70 mm |
|---|---|
| R | 40 mm |
| θ | 29.7° |

It should be noted that the distance D, the effective radius R of the optical attenuator plate, and the divergence angle θ from the intermediate focal point are by no means limited to the above numerical values.

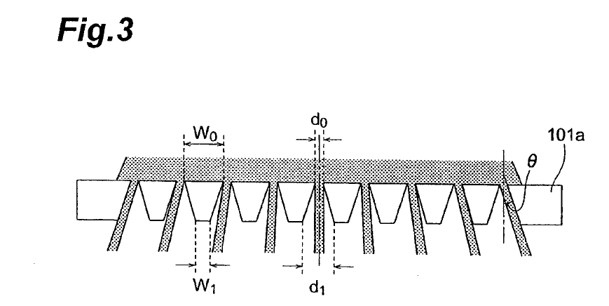

FIG. 3 is a drawing showing a configuration of the optical attenuator plate according to the first embodiment of the present invention in a cross section perpendicular to an acceptance surface thereof. The shaded region in FIG. 3 is a region illuminated with light. In the present embodiment, the openings are of a circular truncated cone shape. An angle of a generator of the circular truncated cone to the direction perpendicular to the acceptance surface of the optical attenuator plate 101a is made equal to the divergence angle θ from the intermediate focal point 203. As a consequence of this configuration, no vignetting is caused even in the openings in the peripheral region of the optical attenuator plate 101a. Therefore, the quantity of light passing through each opening in the peripheral region of the optical attenuator plate 101a is not reduced, compared to the quantity of light passing through the opening at the center of the optical attenuator plate 101a, and the intensity distribution of light after passage through the optical attenuator plate becomes uniform.

The diameter of each opening is d₀ on the surface on the illuminant side and d₁ on the surface on the non-illuminant side. Thus, the diameter of each opening monotonically increases from the illuminant-side surface toward the non-illuminant-side surface. The opening-opening distance (value obtained by subtracting the diameter of the openings from the pitch of the openings) is W₀ on the illuminant-side surface and W₁ on the non-illuminant-side surface.

In the present embodiment, the shapes of all the openings are the same in view of easiness of manufacture. However, the angle of the generator of the circular truncated cone to the direction perpendicular to the acceptance surface of the optical attenuator plate 101a may be determined within the range of 0 to θ, according to the divergence angle from the intermediate focal point 203 at a position of an opening of interest, i.e., according to an angle of a beam at the position of the opening of interest relative to the direction perpendicular to the acceptance surface of the optical attenuator plate 101a.

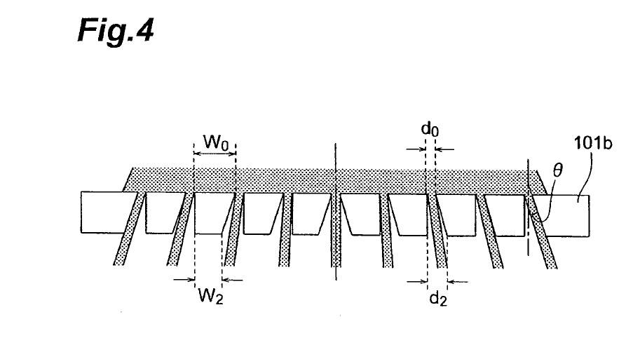

FIG. 4 is a drawing showing a configuration of the optical attenuator plate according to the second embodiment of the present invention in a cross section perpendicular to the acceptance surface thereof. The shaded region in FIG. 4 is a region illuminated with light. In the present embodiment, each opening has a portion of a circular truncated cone shape on the peripheral side of the optical attenuator plate 101b.

Furthermore, each opening has a portion of a circular cylinder shape on the center side of the optical attenuator plate 101b. The angle of the generator of the circular truncated cone to the direction perpendicular to the acceptance surface of the optical attenuator plate 101a is made equal to the divergence angle θ from the intermediate focal point 203. As a consequence of this configuration, no vignetting (shielding of light) is caused even in the openings in the peripheral region of the optical attenuator plate 101b. Therefore, the quantity of light passing through each opening in the peripheral region of the optical attenuator plate 101b is not reduced in comparison with the quantity of light passing through the opening at the center of the optical attenuator plate 101b, and thus the intensity distribution of light after passage through the optical attenuator plate becomes uniform.

The reason why each opening has the portion of the circular cylinder shape on the center side of the optical attenuator plate 101b is as follows. In the first embodiment, the opening-opening distance W₁ on the non-illuminant-side surface can be small in certain cases and there is no flat surface on the non-illuminant side in an extreme case. For forming the openings in the optical attenuator plate, straight holes of a circular cylinder shape are first made and then they are processed into the circular truncated cone shape. However, if the opening-opening distance W₁ is small on the surface on the non-illuminant side, burr or exfoliation will occur to decrease the processing yield. For this reason, as shown in FIG. 4, the portions of the openings on the center side of the optical attenuator plate 101b are formed in the circular cylinder shape so as to make the opening-opening distance on the non-illuminant-side surface larger than that in the case where the whole openings are of the circular truncated cone shape.

The diameter of each opening is d₀ on the illuminant-side surface and d₂ on the non-illuminant-side surface; thus the diameter monotonically increases from the illuminant-side surface toward the non-illuminant-side surface. The opening-opening distance (value obtained by subtracting the diameter of the openings from the pitch of the openings) is W₀ on the illuminant-side surface and W₂ on the non-illuminant-side surface.

When the thickness of the optical attenuator plate is defined as t, the following relation holds.

W₂=W₁+t·tan θ (1)

In the present embodiment, the shapes of all the openings are the same in view of easiness of manufacture. However, the angle of the generator of the circular truncated cone to the direction perpendicular to the acceptance surface of the optical attenuator plate 101b may be determined within the range of 0 to θ, according to the divergence angle from the intermediate focal point 203 at a position of an opening of interest, i.e., according to an angle of a beam at the position of the opening of interest relative to the direction perpendicular to the acceptance surface of the optical attenuator plate 101b.

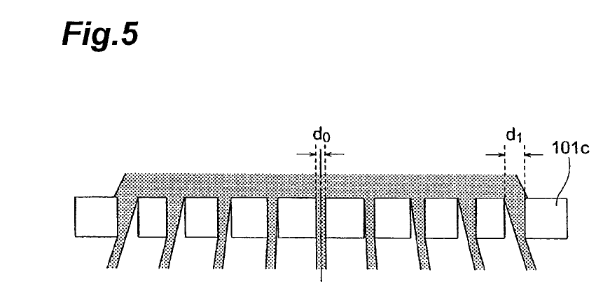

FIG. 5 is a drawing showing a configuration of the optical attenuator plate according to the third embodiment of the present invention in a cross section perpendicular to the acceptance surface thereof. The shaded region in FIG. 5 is a region illuminated with light. In the present embodiment, all the openings are of a circular cylinder shape. In the present embodiment, the diameters of the openings are so defined that the effective area of each opening to the diverging light is equal to the effective area or actual area of the opening at the center of the optical attenuator plate 101c. The effective area of an opening herein is an area of the opening to let a certain quantity of light pass, and, where two openings have an equal effective area, the quantities of light passing through the two openings are equal.

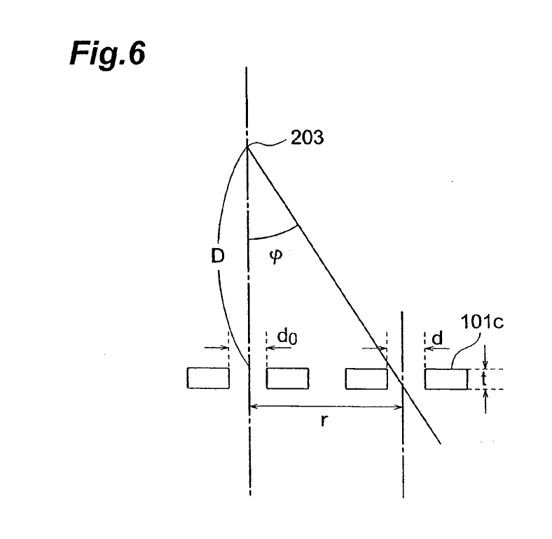

FIG. 6 is a drawing showing a part of an optical system in an exposure apparatus incorporating the optical attenuator plate 101c according to the present embodiment. In FIG. 6, the distance from the intermediate focal point 203 to the optical attenuator plate 101c is denoted by D, the diameter of the opening at the center of the optical attenuator plate 101c is denoted by d₀, the thickness of the optical attenuator plate 101c is denoted by t, the divergence angle of diverging light to illuminate an optionally selected opening is denoted by φ, a distance from the center of the optical attenuator plate 101c to a center of the selected opening is denoted by r, and the diameter of the selected opening is denoted by d. Supposing the thickness t is sufficiently smaller than the distance D, the effective area of the selected opening can be expressed by the formula below. This formula involves subtraction of the area of the shade due to the side wall from the original opening area. It is, however, noted that the unit of angle is radian.

$$S \approx 2 {( \frac{d}{2} )}^{2} {cos}^{- 1} ( \frac{2 a}{d} ) - 2 a \sqrt{{( \frac{d}{2} )}^{2} - {a}^{2}} \qquad ( 2 )$$

In the above formula, the factor a is defined as follows.

a=(t/2)tan φ (3)

On the other hand, the area S₀ of the opening at the center of the optical attenuator plate 101c is given by the following formula.

S₀=π(d₀/2)² (4)

Therefore, the diameter of the opening at the optional position having the effective area equal to the actual area of the opening at the center of the optical attenuator plate 101c, can be obtained by determining d satisfying the following relation.

S=S₀ (5)

Supposing the thickness t of the optical attenuator plate 101c is 0.3 mm and the diameter d₀ of the opening at the center of the optical attenuator plate 101c is 2.3 mm, the diameter d is obtained as follows.

d=0.0472φ²+0.1846φ+2.3002 (6)

By transforming it into the r coordinate system in the optical attenuator plate, the diameter d is expressed by the following formula.

d=0.0472[tan⁻¹(r/D)]²+0.1846[tan⁻¹(r/D)]+2.3002 (7)

As seen from this, once the thickness of the optical attenuator plate 101c and the diameter of the opening at the center of the optical attenuator plate 101c are determined, the diameter of the opening at the optional position having the effective area equal to the actual area of the opening at the center of the optical attenuator plate 101c, is expressed as a function of tan⁻¹(r/D), and the diameter d increases as the distance r from the center of the optical attenuator plate 101c to the center of the optionally selected opening becomes larger.

Since the effective area of the opening at any position becomes equal to the actual area of the opening at the center of the optical attenuator plate 101c, the quantities of light passing through the openings at any two positions become equal to each other and the intensity distribution of light after passage through the optical attenuator plate becomes uniform.

The intensity distribution of light having passed through the optical attenuation filter according to the present invention becomes uniform.

The above embodiments described the examples in the case where the diverging light impinged upon the optical attenuator plate. In the case where converging light impinges upon the optical attenuator plate, the same also applies thereto if the surface opposite to the acceptance surface is used as the acceptance surface.

FIG. 8 is a drawing showing a configuration of an EUV exposure apparatus with an optical attenuator plate according to an embodiment of the present invention. The EUV exposure apparatus includes an illumination optical system 33 and a projection optical system 37.

EUV light emitted from a light source 201 travels via a concave reflecting mirror 34 acting as a collimator mirror, to be converted into a nearly parallel beam, and the nearly parallel beam is incident to an optical integrator 35 consisting of a pair of fly eye mirrors 35a and 35b.

In this manner, a substantial surface illuminant with a predetermined shape is formed near a reflecting surface of the fly eye mirror 35a, i.e., near an exit surface of the optical integrator 35. The light from the substantial surface illuminant is deflected by a plane reflecting mirror 36 and thereafter the deflected light forms an illumination region of an elongated arcuate shape on a mask M. An aperture plate for forming the arcuate illumination region is not illustrated herein. The light reflected on the surface of the mask M is then reflected in order by multilayer reflecting mirrors M1, M2, M3, M4, M5, and M6 of the projection optical system 37 to be focused as exposure light 1, and the exposure light 1 forms an image of a pattern formed on the surface of the mask M, on a resist 3 applied on a wafer 2.

The optical attenuator plate 101 is located upstream of the illumination optical system 33. An attenuation rate by the optical attenuator plate 101 is adjusted so that the illuminance on the wafer 2 becomes a desired value. A tablet plate with the optical attenuator plate 101 may be arranged at the position of the optical attenuator plate 101.

When the optical attenuator plate according to the present invention is used, the intensity distribution of the exposure light can be made uniform across the entire exposure region, so as to improve the exposure accuracy of the exposure apparatus.

If a nonuniform intensity distribution of exposure light is desired in the exposure region, it can be realized by suitably determining the diameter of the openings and the arrangement of the openings according to the intensity distribution to be obtained.

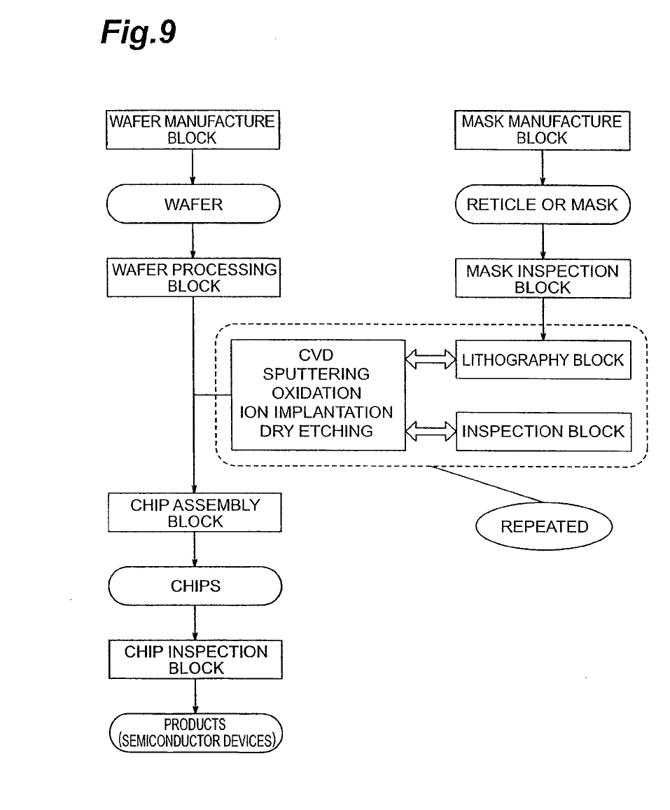

The following will describe an example of an embodiment of a semiconductor device manufacturing method according to the present invention. FIG. 9 is a flowchart showing the example of the embodiment of the semiconductor device manufacturing method according to the present invention. Manufacturing blocks in this example include the following blocks.

(1) Wafer manufacture block to manufacture a wafer (or a wafer preparation block to prepare a wafer).

(2) Mask manufacture block to manufacture a mask used for exposure (or a mask preparation block to prepare a mask).

(3) Wafer processing block to perform a necessary exposure process for the wafer.

(4) Chip assembly block to cut chips formed on the wafer, one by one and make each chip operable.

(5) Chip inspection block to inspect each chip obtained.

It is noted that each of the above blocks consists of sub-blocks.

Among these main blocks, a main block having a decisive influence on the performance of semiconductor devices is the wafer processing block. In this block, designed circuit patterns are successively layered on the wafer to form a large number of chips to operate as memories and MPU. This wafer processing block includes the following blocks.

(1) Thin film forming block to form a dielectric film to become an insulating layer, a metal thin film to form wiring portions or electrode portions, and so on (by CVD, sputtering, or the like).

(2) Oxidation block to oxidize the thin film layer and/or the wafer substrate.

(3) Lithography block to form a pattern of a resist using a mask (reticle), in order to selectively process the thin film layer, the wafer substrate, or the like.

(4) Etching block to process the thin film layer and/or the substrate according to the resist pattern (e.g., by the dry etching technique).

(5) Ion/impurity implantation & diffusion block.

(6) Resist removing block.

(7) Inspection block to inspect the processed wafer.

The wafer processing block is repeatedly carried out a number of times necessary for required layers, thereby manufacturing semiconductor devices to operate as designed.

In the present embodiment, the EUV light exposure apparatus with the optical attenuator plate according to the present invention is used in the foregoing lithography block. Therefore, the intensity distribution of the exposure light can be made uniform across the entire exposure region whereby the exposure accuracy in the lithography block is improved.

FIG. 2 showed the example wherein the shape of the openings was circular and wherein the circular openings were arranged at the equal pitch in the two-dimensional directions, but the present invention is by no means limited to this shape and arrangement. A variety of modification examples can be contemplated as to the shape and arrangement: for example, the shape of the openings may be any other shape such as a square, and the arrangement of the openings can be such that the openings are arranged in a staggered pattern in the vertical direction and/or in the horizontal direction, or such that the openings are concentrically arranged.

The optical attenuator plate of the embodiments of the present invention uniformizes the intensity distribution of light passing therethrough and, when used in the exposure apparatus, it realizes the uniform light intensity on the exposure target surface.

As described above, the present invention is not limited to the above-described embodiments but can be carried out in various configurations without departing from the spirit and scope of the present invention. Also, the components disclosed in the embodiments may be assembled in any combination for embodying the present invention. For example, some of the components may be omitted from all components disclosed in the embodiments. Further, components in different embodiments may be appropriately combined.

1. An optical attenuator plate to adjust a quantity of light from a light source, said optical attenuator plate comprising a plurality of high-transmittance regions with a relatively high transmittance, the high-transmittance regions having respective shapes defined such that an intensity distribution of a beam of diverging light or converging light having passed through the optical attenuator plate is uniform.

2. The optical attenuator plate according to claim 1, wherein a cross section, parallel to an acceptance surface of the optical attenuator plate, of at least one of the plurality of high-transmittance regions varies along a traveling direction of the light beam so that the intensity distribution of the light beam having passed through the optical attenuator plate is uniform.

3. The optical attenuator plate according to claim 2, wherein the cross section becomes progressively larger along the traveling direction of the light beam.

4. The optical attenuator plate according to claim 2, wherein at least a part of an outer edge of a cross section along a direction perpendicular to the acceptance surface of the optical attenuator plate, of said at least one of the high-transmittance regions, has a predetermined angle to the direction perpendicular to the acceptance surface of the optical attenuator plate.

5. The optical attenuator plate according to claim 3, wherein at least a part of an outer edge of a cross section, along a direction perpendicular to the acceptance surface of the optical attenuator plate, of said at least one of the high-transmittance regions has a predetermined angle to the direction perpendicular to the acceptance surface of the optical attenuator plate.

6. The optical attenuator plate according to claim 4, wherein, where the beam of diverging light passes through the optical attenuator plate, the predetermined angle is not more than a maximum angle of the beam of diverging light to the direction perpendicular to the acceptance surface of the optical attenuator plate.

7. The optical attenuator plate according to claim 4, wherein only an outside portion in the optical attenuator plate, of the outer edge of the cross section along the direction perpendicular to the acceptance surface of the optical attenuator plate, of said at least one of the high-transmittance regions has the predetermined angle to the direction perpendicular to the optical attenuator plate.

8. The optical attenuator plate according to claim 5, wherein only an outside portion in the optical attenuator plate, of the outer edge of the cross section along the direction perpendicular to the acceptance surface of the optical attenuator plate, of said at least one of the high-transmittance regions has the predetermined angle to the direction perpendicular to the optical attenuator plate.

9. The optical attenuator plate according to claim 1, wherein, among the plurality of high-transmittance regions, each said region has a size in an outside region that is larger than a size in an inside region so that the intensity distribution of the light having passed through the optical attenuator plate is uniform.

10. The optical attenuator plate according to claim 8, wherein a size of a certain high-transmittance region, of the plurality of high-transmittance regions, is defined in consideration of an angle of the beam of diverging light or converging light at a position of said high-transmittance region, relative to the direction perpendicular to an acceptance surface of the optical attenuator plate.

11. The optical attenuator plate according to claim 1, wherein the high-transmittance regions are openings in a plate that does not transmit the light.

12. The optical attenuator plate according to claim 1, wherein the optical attenuator plate is comprised of molybdenum or tungsten or a compound containing either thereof, and the wavelength is an EUV wavelength.

13. An exposure apparatus comprising the optical attenuator plate according to claim 1, situated in at least one optical path of the apparatus.

14. An exposure method comprising transferring an exposure pattern, formed on a mask, onto a photo-sensitive substrate to effect exposure of said substrate, the exposure being performed using an exposure apparatus comprising the optical attenuator plate according to claim 1.

15. A device manufacturing method comprising:
transferring an exposure pattern formed on a mask, onto a photo-sensitive substrate to effect exposure of the substrate, the exposure being performed using an exposure apparatus comprising the optical attenuator plate according to claim 1.

16. An optical attenuator plate to adjust a quantity of light from a light source, said optical attenuator plate comprising:
a base plate including a first surface that is a light-incident side and a second surface that is a light-exit side;
the first surface including a plurality of high-transmittance regions with a relatively high transmittance; and
the second surface including a plurality of high-transmittance regions with a relatively high transmittance;
wherein the high-transmittance regions on the first surface and the high-transmittance regions on the second surface have respective shapes that are different from each other.

17. The optical attenuator plate according to claim 16, wherein a size of a cross section parallel to the first surface of the base plate, of at least one of the plurality of high-transmittance regions, varies along a traveling direction of the light beam so that the intensity distribution of the light beam having passed through the optical attenuator plate is uniform.

18. The optical attenuator plate according to claim 17, wherein the cross section becomes progressively larger along the traveling direction of the light beam.

19. The optical attenuator plate according to claim 17, wherein at least a part of an outer edge of a cross section, along a direction perpendicular to the first surface of the first plate, of said at least one of the high-transmittance regions has a predetermined angle to the direction perpendicular to the first surface of the base plate.

20. The optical attenuator plate according to claim 16, wherein the high-transmittance regions are openings.

21. An exposure apparatus comprising the optical attenuator plate according to claim 16 in at least one optical path of said apparatus.

22. A device manufacturing method comprising:
transferring an exposure pattern formed on a mask, onto a photo-sensitive substrate to effect exposure thereof, the transferring being performed using an exposure apparatus comprising the optical attenuator plate according to claim 16.
